(19) United States
(12) Patent Application Publication
(10) Pub. No.: US 2025/0300058 A1
(43) Pub. Date: Sep. 25, 2025

(54) SEMICONDUCTOR PACKAGE

(71) Applicant: SAMSUNG ELECTRONICS CO., LTD., Suwon-si (KR)

(72) Inventors: Seokbeom YONG, Suwon-si (KR); Sang Sub SONG, Suwon-si (KR); Seulgi YU, Suwon-si (KR)

(73) Assignee: SAMSUNG ELECTRONICS CO., LTD., Suwon-si (KR)

(21) Appl. No.: 18/909,098

(22) Filed: Oct. 8, 2024

(30) Foreign Application Priority Data
Mar. 19, 2024 (KR) 10-2024-0038106

(51) Int. Cl. H01L 23/498; H01L 23/00; H01L 23/15

(52) U.S. Cl. CPC H01L 23/49838; H01L 23/49822; H01L 24/16; H01L 23/15; H01L 2224/16227

(57) ABSTRACT

A semiconductor package according to an embodiment includes a substrate including a first signal layer, a core layer on the first signal layer, and a second signal layer on the core layer; a redistribution structure disposed on the substrate and including a plurality of redistribution lines; and a semiconductor die on the redistribution structure. A signal transmitted to or from the semiconductor die is routed through a first horizontal path within the first signal layer; a first vertical path extending from the first signal layer to a corresponding redistribution line among the plurality of redistribution lines; a second horizontal path within the corresponding redistribution line; and a second vertical path extending from the corresponding redistribution line to the semiconductor die.

### CROSS-REFERENCE TO RELATED APPLICATION

This application claims priority to and the benefit of Korean Patent Application No. 10-2024-0038106 filed in the Korean Intellectual Property Office on Mar. 19, 2024, the entire contents of which are incorporated herein by reference.

### BACKGROUND OF THE DISCLOSURE

### (a) Field of the Disclosure

The present disclosure relates to a semiconductor package.

### (b) Description of the Related Art

In accordance with a recent trend of down-sized and high-performance of electron products, a demand for a 2.5D semiconductor package that may form multiple semiconductor chips into a single package by placing an interposer on a substrate and placing multiple semiconductor chips horizontally on the interposer is increasing. In addition, in order to achieve higher density and efficiency, based on this 2.5D semiconductor package, a new semiconductor package technology is being developed by modifying some of the structures and materials of the 2.5D semiconductor package.

The semiconductor package based on the 2.5D semiconductor package applies high-speed interface IP such as a PCIe or a SerDes, signals of these high-speed interfaces IP must be balled out, and an Rx signal and a Tx signal must be routed in different layers. Additionally, the substrate of the semiconductor package to which high-speed interface IP is applied must be designed to have a strip line structure in which ground layers are disposed above and below the signal layer to reduce a crosstalk. Additionally, if the substrate of the semiconductor package is an organic substrate, a diameter of a via in a core layer within the substrate is larger than a diameter of a bump that connects the semiconductor chip and the interposer. Therefore, the layout of the core via cannot overlap the layout of the bump, so the signals cannot be transmitted directly from the bump at the bottom of the semiconductor chip to the bottom of the core layer, and all signals must be routed in the horizontal direction from the top of the core layer.

If the wire structure within the substrate is designed by taking all of these points into consideration, five conductive layers of a ground layer-a signal layer-a ground layer-a signal layer-a ground layer are required in minimum on the top of the core layer, and the substrate requires a total of ten conductive layers, including the same number of conductive layers below the core layer. Here, if a power layer is added to supply the power required for high-speed interface IP, the substrate will require at least 12 to 14 conductive layers.

The large number of conductive layers within the substrate causes a complex signal transmission path to be formed between semiconductor chips and between the semiconductor chip and the substrate, so the development of a new semiconductor package technology that may improve this is necessary.

### SUMMARY OF THE DISCLOSURE

In a semiconductor package including a substrate that includes a lower stacking structure, a core layer on the lower stacking structure, and an upper stacking structure on the core layer, a redistribution structure on the substrate, and a semiconductor die on the redistribution structure, the redistribution structure may be in directly contact with the substrate, and the substrate may be formed with a material that may form a small diameter of a core via within the core layer. As a result, vertical signal wires that penetrate the upper stacking structure and the core layer within the substrate may be formed, and a signal layer that routes a signal in a horizontal direction may be formed on the lower stacking structure of the substrate.

If the spacing of the core vias in the core layer is designed according to a spacing (a pitch) of bumps connecting the semiconductor die and the redistribution structure, neighboring vertical signal wires are disposed with a narrow spacing, resulting in an insertion loss and a return loss may be worsen. Therefore, the spacing between the neighboring vertical signal wires may be secured using a redistribution line within the redistribution structure.

A semiconductor package according to an embodiment includes a substrate including a first signal layer, a core layer on the first signal layer, and a second signal layer on the core layer; a redistribution structure disposed on the substrate and including a plurality of redistribution lines; and a semiconductor die on the redistribution structure. A signal transmitted to or from the semiconductor die is routed through a first horizontal path within the first signal layer; a first vertical path extending from the first signal layer to a corresponding redistribution line among the plurality of redistribution lines; a second horizontal path within the corresponding redistribution line; and a second vertical path extending from the corresponding redistribution line to the semiconductor die.

A semiconductor package according to an embodiment includes a substrate including a first signal layer, a core layer on the first signal layer, and a second signal layer on the core layer; a redistribution structure disposed on the substrate and including a plurality of redistribution lines; and a semiconductor die on the redistribution structure. Each of a first signal and a second signal transmitted to or from the semiconductor die is routed through a first horizontal path within the first signal layer; a first vertical path extending from the first signal layer to a corresponding redistribution line among the plurality of redistribution lines; a second horizontal path within the corresponding redistribution line; and a second vertical path extending from the corresponding redistribution line to the semiconductor die, the first vertical path of the first signal and the first vertical path of the second signal extend with a first spacing in a horizontal direction, the second vertical path of the first signal and the second vertical path of the second signal extend with a second spacing in the horizontal direction, and the first spacing is greater than the second spacing.

A semiconductor package according to an embodiment includes a substrate, wherein the substrate includes a signal layer including a plurality of signal lines; a plurality of first signal vias on the plurality of signal lines; a core layer including a plurality of core through vias on the plurality of first signal vias; and a plurality of second signal vias on the plurality of core through vias, a redistribution structure on the substrate, wherein the redistribution structure includes a plurality of first redistribution signal vias on the plurality of second signal vias; a plurality of redistribution signal lines on the plurality of first redistribution signal vias; and a plurality of second redistribution signal vias on the plurality of redistribution signal lines, a plurality of connection members on the redistribution structure; and a semiconductor die on the plurality of connection members, each of a plurality of signals transmitted to or from the semiconductor die is routed through one first horizontal path among the plurality of signal lines; a first vertical path through one of the plurality of first signal vias, one of the plurality of core through vias, one of the plurality of second signal vias, and one of the plurality of first redistribution signal vias; one second horizontal path among the plurality of second redistribution signal lines; and a second vertical path through one of the plurality of second redistribution signal vias and one of the plurality of connection members, the first vertical paths of the neighboring signals among the plurality of signals extend with a first spacing in a horizontal direction, the second vertical paths of the neighboring signals among the plurality of signals extend with a second spacing in the horizontal direction, and the first spacing is greater than the second spacing.

By providing the semiconductor package that includes the substrate made of the material that may form the small diameter of the core via in the core layer, and the redistribution structure that is in direct contact with the substrate, it is possible to form the vertical signal wires that penetrate the upper stacking structure and the core layer within the substrate, and to form the signal layer that routes the signal in the horizontal direction to the lower stacking structure of the substrate. As a result, the number of the conductive layers within the substrate may be reduced, thereby reducing the size of the semiconductor package, and the signal transmission path between the semiconductor chip and the substrate may be implemented more efficiently.

In addition to the proposed structure, an insertion loss and a return loss may be improved by securing the spacing of the neighboring vertical signal wires by using the redistribution line in the redistribution structure, thereby improving a signal integrity (SI).

### BRIEF DESCRIPTION OF THE DRAWINGS

FIG. 1 is a cross-sectional view showing a semiconductor package of an embodiment.

FIG. 2 is a view showing an arrangement of conductive layers of a conventional substrate.

FIG. 3 is a top plan view showing a layout of bumps of an embodiment.

FIG. 4 is a view of an arrangement of conductive layers of a substrate of FIG. 1.

FIG. 5 is a perspective view showing a comparative example of a region A of a semiconductor package in FIG. 1.

FIG. 6 is an enlarged perspective view of a region A of a semiconductor package in FIG. 1.

FIG. 7 is a graph showing a comparison of an insertion loss for a region A of a conventional semiconductor package and an insertion loss for a region A of a semiconductor package according to an embodiment.

FIG. 8 is a graph showing a comparison of a return loss for a region A of a conventional semiconductor package and a return loss for a region A of a semiconductor package according to an embodiment.

FIG. 9 is a cross-sectional view showing a semiconductor package of another embodiment.

FIG. 10 is a view of an arrangement of conductive layers of a substrate in FIG. 9.

FIG. 11 is a cross-sectional view showing a semiconductor package according to another embodiment.

FIG. 12 is a view of an arrangement of conductive layers of a substrate in FIG. 11.

### DETAILED DESCRIPTION OF THE EMBODIMENTS

Hereinafter, examples of the present disclosure will be described in detail with reference to the accompanying drawings so that those of ordinary skill in the art may easily implement the present disclosure. However, the present disclosure may be implemented in various different forms and is not limited to the examples described herein.

In the drawings, elements irrelevant to the description of the present disclosure are omitted for simplicity of explanation, and like reference numerals designate like elements throughout the specification.

Further, in the drawings, a size and thickness of each element are randomly represented for better understanding and ease of description, and the present disclosure is not limited thereto.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise”, and variations such as “comprises” or “comprising”, will be understood to imply the inclusion of stated elements but not the exclusion of any other elements.

Also, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioning on or below the object portion, and does not necessarily mean positioning on the upper side of the object portion based on a gravity direction.

Further, in the specification, the word “in a plane view” means when an object portion is viewed from the above, and the word “in cross section” means when a cross section taken by vertically cutting an object portion is viewed from the side.

Hereinafter, a semiconductor package 100 according to an embodiment will be described with reference to accompanying drawings.

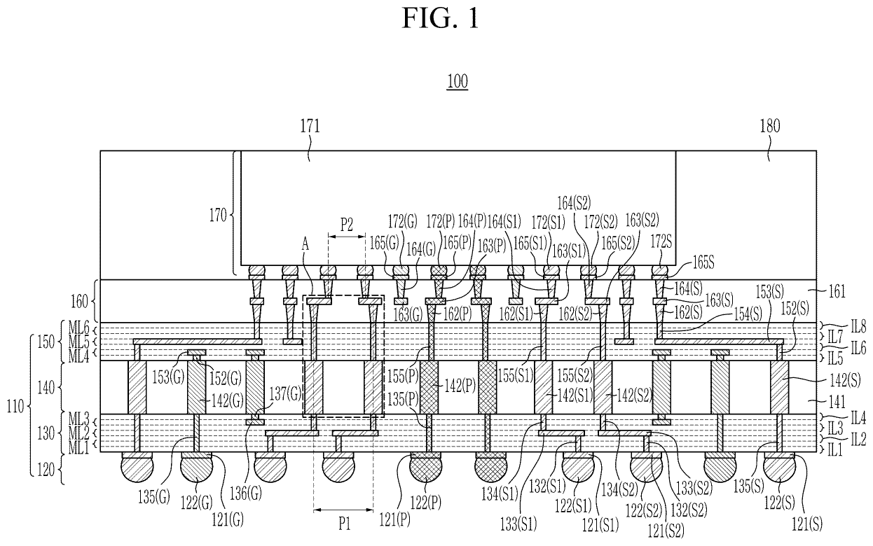

FIG. 1 is a cross-sectional view showing a semiconductor package 100 according to an embodiment.

Referring to FIG. 1, the semiconductor package 100 includes a substrate 110, a redistribution structure 160, a semiconductor chip 170, and a molding material 180. In an embodiment, the semiconductor package 100 may be a semiconductor package whose structures and materials have been changed based on a 2.5D semiconductor package. In an embodiment, the semiconductor package 100 may be a semiconductor package to which a high-speed interface IP such as PCIe or SerDes is applied. In an embodiment, the semiconductor package 100 may be manufactured based on a fan out wafer level package (FOWLP) or a fan out panel level package (FOPLP) technology.

According to the present disclosure, S is added to an end of a reference numeral in a configuration corresponding to a wire path transmitting a signal, P is added to an end of a reference numeral in a configuration corresponding to a wire path that transmits an electric power, and G is added to an end of a reference numeral in a configuration corresponding to a wire path connected to a ground. Additionally, in order to distinguish the wire path that transmits the signals, the wire path that transmits the electric power, and the wire path that is connected to the ground, patterns are differently displayed for each wire path. Therefore, even if the reference numeral is not displayed, the configuration with the same pattern as the pattern of the configuration with S added to the end of the reference numeral indicates the wire path that transmits the signal, the configuration with the same pattern as the pattern of the configuration with P added to the end of the reference numeral indicates the wire path that transmits the electric power, and the configuration with the same pattern as the pattern of the configuration with G added to the end of the reference numeral indicates the wire path connected to the ground.

The substrate 110 includes an external connection structure 120, a lower stacking structure (a first stacking structure; 130), a core layer 140, and an upper connection structure (a second stacking structure; 150). In an embodiment, the substrate 110 may include a printed circuit board (PCB). In one embodiment, the substrate 110 may include a glass substrate or an organic substrate.

The external connection structure 120 is disposed on the bottom surface of the lower stacking structure 130. The external connection structure 120 includes connection pads 121 and external connection members 122. Each of the connection pads 121 is disposed between each of the vias of the lower stacking structure 130 and each of the external connection members 122. Each of the connection pads 121 electrically connects each of the vias of the lower stacking structure 130 to each of the external connection members 122. In an embodiment, the connection pads 121 may include at least one of copper, nickel, zinc, gold, silver, platinum, palladium, chromium, titanium, and alloys thereof.

The external connection members 122 electrically connect the semiconductor package 100 to an external device (not shown). Each of the external connection members 122 is disposed below each of the connection pads 121. Each of the external connection members 122 is electrically connected to each of the connection pads 121. In an embodiment, the external connection members 122 may include bumps or solder balls. In an embodiment, the external connection members 122 may include at least one of tin, silver, lead, nickel, copper or alloys thereof.

The lower stacking structure 130 includes N stacked conductive layers. In an embodiment, N may be 3. The lower stacking structure 130 includes first conductive layer ML1 to third conductive layer ML3, and first dielectric material layer IL1 to fourth dielectric material layer IL4. The first conductive layer ML1 to the third conductive layer ML3 and the first dielectric material layer IL1 to the fourth dielectric material layer IL4 are stacked sequentially and alternating with each other.

The first dielectric material layer IL1 is disposed at the bottom of the lower stacking structure 130. The first dielectric material layer IL1 is disposed below the first conductive layer ML1. The first dielectric material layer IL1 includes vias connecting the first conductive layer ML1 to the connection pads 121.

The first conductive layer ML1 is disposed between the first dielectric material layer IL1 and the second dielectric material layer IL2. In an embodiment, the first conductive layer ML1 may be the first ground layer. In an embodiment, the first conductive layer ML1 may include a ground structure. In an embodiment, the ground structure may be formed of a conductive member of a mesh shape. In an embodiment, the ground structure within the first conductive layer ML1 is surrounded by a dielectric material. In an embodiment, the ground structure may extend in a first horizontal direction and in a second horizontal direction that intersects the first horizontal direction.

The second dielectric material layer IL2 is disposed between the first conductive layer ML1 and the second conductive layer ML2. Within the second dielectric material layer IL1, vias connecting the second conductive layer ML2 to the first conductive layer ML1 are included.

The second conductive layer ML2 is disposed between the second dielectric material layer IL2 and the third dielectric material layer IL3. In an embodiment, the second conductive layer ML2 may be the first signal layer. In an embodiment, the second conductive layer ML2 may include signal lines. In an embodiment, the signal lines within the second conductive layer ML2 are surrounded by a dielectric material. In an embodiment, the signal lines may extend in the horizontal direction.

The third dielectric material layer IL3 is disposed between the second conductive layer ML2 and the third conductive layer ML3. Within the third dielectric material layer IL3, vias that connect the third conductive layer ML3 to the second conductive layer ML2 are included.

The third conductive layer ML3 is disposed between the third dielectric material layer IL3 and the fourth dielectric material layer IL4. In an embodiment, the third conductive layer ML3 may be the second ground layer. In an embodiment, the ground structure may be formed of a conductive member of a mesh shape. In an embodiment, the ground structure within the third conductive layer ML3 is surrounded by a dielectric material. In an embodiment, the ground structure may extend in the first horizontal direction and in the second horizontal direction that intersects the first horizontal direction.

The fourth dielectric material layer IL4 is disposed on the top of the lower stacking structure 130. The fourth dielectric material layer IL4 is disposed between the third conductive layer ML3 and the core layer 140. Within the fourth dielectric material layer IL4, vias connecting the core vias to the third conductive layer ML3 are included.

The lower stacking structure 130 includes conductive pads 121, first conductive layer ML1 to third conductive layer ML3, and vias that connect core through vias 142 to each other in the vertical direction.

In an embodiment, the signal lines, the ground structure, and the vias of the lower stacking structure 130 may each include at least one of copper, aluminum, tungsten, nickel, gold, tin, titanium, and alloys thereof. In an embodiment, a dielectric material surrounding the signal lines, the ground structure, and the vias, and the dielectric material of the first dielectric material layer IL1 to the fourth dielectric material layer IL4 may include a glass fiber (a resin impregnated fiber glass cloth) implanted with a synthetic resin such as a woven glass mat (glass-epoxy) with an immersed epoxy, polyimide, FR-4, resin cyanate ester, TEFLON (tetrafluoroethylene) (PTFE), polyethylene ether, and a mixture thereof.

The core layer 140 is disposed on the lower stacking structure 130. The core layer 140 includes a core 141 and core through vias 142. In an embodiment, the core 141 may include a glass core. In an embodiment, the glass core may include borosilicate glass, quartz or alkali-free glass. This glass material has a surface roughness of 10 nm or less. In addition, because the thermal expansion coefficient of the glass material is similar to that of silicon, the semiconductor package using the glass material may reduce a warpage. Therefore, the glass material is more advantageous in forming the fine circuit pattern than the polymer material that was conventionally used as the core of the substrate, and when the glass material is used to form the glass core, the diameter of the glass core through via may be formed similar to the diameter of the bump that connects the semiconductor die and the redistribution structure, thereby it is possible to form a signal vertical path that passes from the upper stacking structure of the substrate through the glass core through via to the lower stacking structure. In another embodiment, the core 141 may include an organic core or a polymer core.

The core through vias 142 are positioned within the core 141. In an embodiment, the core through vias 142 may be through glass vias (TGV). In an embodiment, the core through vias 142 may be formed by performing a laser processing or a mechanical processing on the core 141. In an embodiment, the core through vias 142 may be formed by completely filling the interior of the via hole penetrating the core 141 with a conductive material. In an embodiment, the core through vias 142 may be formed by conformally forming a conductive material along the inner wall of the via hole and filling the remaining space of the via hole with a dielectric material. In an embodiment, the conductive material within the core through vias 142 may include at least one of copper, aluminum, tungsten, nickel, gold, tin, titanium, and alloys thereof. In an embodiment, the dielectric material of the core through vias 142 may include a glass fiber (a resin impregnated fiber glass cloth) implanted with a synthetic resin such as a woven glass mat (glass-epoxy) with an immersed epoxy, polyimide, FR-4, resin cyanate ester, TEFLON (tetrafluoroethylene) (PTFE), polyethylene ether, and a mixture thereof. In an embodiment, the diameter of each of the core through vias 142 in the horizontal direction may be about 30 μm to about 120 μm. In an embodiment, the spacing between the neighboring core through vias among the core through vias 142 in the horizontal direction may be about 200 μm to about 500 μm. For example, the expression being “about” a value may refer to being exactly the value, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

The upper stacking structure 150 is disposed on the core layer 140. The upper stacking structure 150 includes M stacked conductive layers. In an embodiment, M may be 3. The upper stacking structure 150 includes fourth conductive layer ML4 to sixth conductive layer ML6 and fifth dielectric material layer IL5 to eighth dielectric material layer IL8. The fourth conductive layer ML4 to the sixth conductive layer ML6 and the fifth dielectric material layer IL5 to the eighth dielectric material layer IL8 are stacked sequentially and alternatively with each other.

The fifth dielectric material layer IL5 is disposed at the bottom of the upper stacking structure 150. The fifth dielectric material layer IL5 is disposed between the core layer 140 and the fourth conductive layer ML4. The fifth dielectric material layer IL5 includes vias connecting the fourth conductive layer ML4 to the core through vias 142 of the core layer 140.

The fourth conductive layer ML4 is disposed between the fifth dielectric material layer IL5 and the sixth dielectric material layer IL6. In an embodiment, the fourth conductive layer ML4 may be the third ground layer. In an embodiment, the fourth conductive layer ML4 may include a ground structure. In an embodiment, the ground structure may be formed of a conductive member of a mesh shape. In an embodiment, the ground structure within the first conductive layer ML4 is surrounded by a dielectric material. In an embodiment, the ground structure may extend in a first horizontal direction and in a second horizontal direction that intersects the first horizontal direction.

The sixth dielectric material layer IL6 is disposed between the fourth conductive layer ML4 and the fifth conductive layer ML5. The sixth dielectric material layer IL6 includes vias connecting the fifth conductive layer ML5 to the fourth conductive layer ML4.

The fifth conductive layer ML5 is disposed between the sixth dielectric material layer IL6 and the seventh dielectric material layer IL7. In an embodiment, the fifth conductive layer ML5 may be the second signal layer. In an embodiment, the fifth conductive layer ML5 may include signal lines. In an embodiment, the signal lines within the fifth conductive layer ML5 are surrounded by a dielectric material. In an embodiment, the signal lines may extend in the horizontal direction.

The seventh dielectric material layer IL7 is disposed between the fifth conductive layer ML5 and the sixth conductive layer ML6. Within the seventh dielectric material layer IL7, vias connecting the sixth conductive layer ML6 to the fifth conductive layer ML5 are included.

The sixth conductive layer ML6 is disposed between the seventh dielectric material layer IL7 and the eighth dielectric material layer IL8. In an embodiment, the sixth conductive layer ML6 may be the fourth ground layer. In an embodiment, the ground structure may be formed of a conductive member of a mesh shape. In an embodiment, the ground structure within the sixth conductive layer ML6 is surrounded by a dielectric material. In an embodiment, the ground structure may extend in a first horizontal direction and in a second horizontal direction that intersects the first horizontal direction.

The eighth dielectric material layer IL8 is disposed on the top of the upper stacking structure 150. The eighth dielectric material layer IL8 is disposed between the sixth conductive layer ML6 and the redistribution structure 160. Within the eighth dielectric material layer IL8, vias connecting the first redistribution vias 162 of the redistribution structure 160 to the sixth conductive layer ML6 are included.

The upper stacking structure 150 includes vias connecting the core through vias 142, the first conductive layer ML1 to the third conductive layer ML3, and the first redistribution vias 162, respectively, in the vertical direction.

In an embodiment, the signal lines, the ground structures, and the vias of the upper stacking structure 150 may each include at least one of copper, aluminum, tungsten, nickel, gold, tin, titanium, and alloys thereof. In an embodiment, the dielectric material surrounding the signal lines, the ground structures, and the vias, and the dielectric material of the fifth dielectric material layer IL5 to the eighth dielectric material layer IL8 may include a glass fiber (a resin impregnated fiber glass cloth) implanted with a synthetic resin such as a woven glass mat (glass-epoxy) with an immersed epoxy, polyimide, FR-4, resin cyanate ester, TEFLON (tetrafluoroethylene) (PTFE), polyethylene ether, and a mixture thereof. In another embodiment, the substrate 110 including the fewer or more external connection members, connection pads, signal lines, ground structures, vias, and core through vias is included within the scope of the present disclosure.

The redistribution structure 160 is disposed on the substrate 110. The redistribution structure 160 is disposed on the upper stacking structure 150 of the substrate 110. The redistribution structure 160 includes a dielectric material 161, a first redistribution vias 162 within the dielectric material 161, redistribution lines 163, second redistribution vias 164, and bonding pads 165 on the dielectric material 161. In an embodiment, the redistribution structure 160 may be formed on the substrate 110. In one embodiment, the redistribution structure 160 may be completed through a separate process from the substrate 110 and then attached to the substrate 110 without connecting members. In one embodiment, the bottom surface of the redistribution structure 160 may be in contact with the upper surface of the upper stacking structure 150 of the substrate 110.

The dielectric material 161 protects and insulates the first redistribution vias 162, the redistribution lines 163, and the second redistribution vias 164. The semiconductor die (a semiconductor chip; 170) and the molding material 180 are disposed on the upper surface of the dielectric material 161. An upper stacking structure 150 is disposed on the bottom surface of the dielectric material 161. The dielectric material 161 may include a photoimageable dielectric (PID) used in the redistribution layer process. As an embodiment, the photosensitive dielectric material (PID) may include polyimide-based photoactive polymer, novolac-based photoactive polymer, polybenzoxazole, silicon-based polymer, acrylate-based polymer, or epoxy-based polymer.

Each of the first redistribution vias 162 is disposed between each of the redistribution lines 163 and each of the vias within the upper stacking structure 150. Each of the first redistribution vias 162 electrically connect each of the redistribution lines 163 to each of the vias in the upper stacking structure 150 in the vertical direction.

Each of the redistribution lines 163 is disposed between each of the first redistribution vias 162 and each of the second redistribution vias 164. Each of the redistribution lines 163 electrically connects each of the first redistribution vias 162 to each of the second redistribution vias 164 in the horizontal direction.

Each of the second redistribution vias 164 is disposed between each of the redistribution lines 163 and each of the bonding pads 165. Each of the second redistribution vias 164 electrically connects each of the bonding pads 165 to each of the redistribution lines 163 in the vertical direction.

Each of the bonding pads 165 is disposed between each of the second redistribution vias 164 and each of the connection members 172. Each of the bonding pads 165 electrically connect each of the connection members 172 to each of the second redistribution vias 164.

In another embodiment, the redistribution structure 160 including fewer or more redistribution lines, redistribution vias, and bonding pads is included within the scope of the present disclosure.

The semiconductor die 170 is disposed on the redistribution structure 160. The semiconductor die 170 is plural, and the redistribution structure 160 connects the plurality of semiconductor dies 170 in the horizontal direction. The semiconductor die 170 includes a die base 171 and connection members 172. In an embodiment, the semiconductor die 170 may include a logic die or a memory die. In an embodiment, the semiconductor die 170 may include a system on chip (SoC) or an application processor (AP). In an embodiment, the semiconductor die 170 may include at least one of a central processing unit (CPU) and a graphic processing unit (GPU). In an embodiment, the semiconductor die 170 may include a high bandwidth memory (HBM).

Each of the connection members 172 is disposed between each of the bonding pads 165 of the redistribution structure 160 and the die base 171. Each of the connection members 172 electrically connects the die base 171 to each of the bonding pads 165 of the redistribution structure 160. In an embodiment, the connection members 172 may include micro bumps. In an embodiment, the connection members 172 may include at least one of tin, gold, silver, lead, nickel, copper, titanium, or alloys thereof. In an embodiment, the diameter of the connection member 172 in the horizontal direction may be about 30 μm to about 120 μm. In an embodiment, the spacing between neighboring connection members in the horizontal direction among connection members 172 may be about 50 μm to about 180 μm.

The molding material 180 is disposed on the redistribution structure 160 and covers the semiconductor die 170. In an embodiment, the molding material 180 may include an epoxy molding compound (EMC).

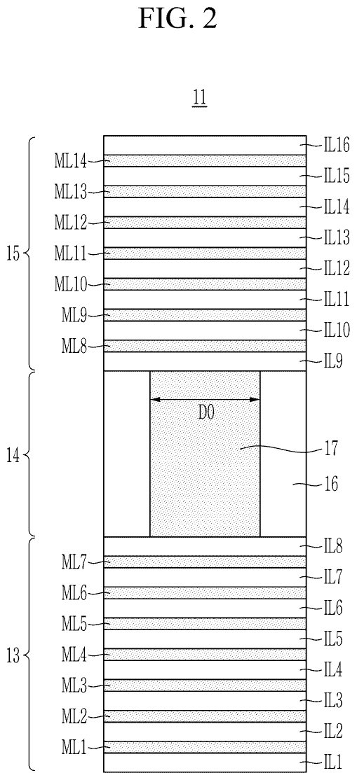

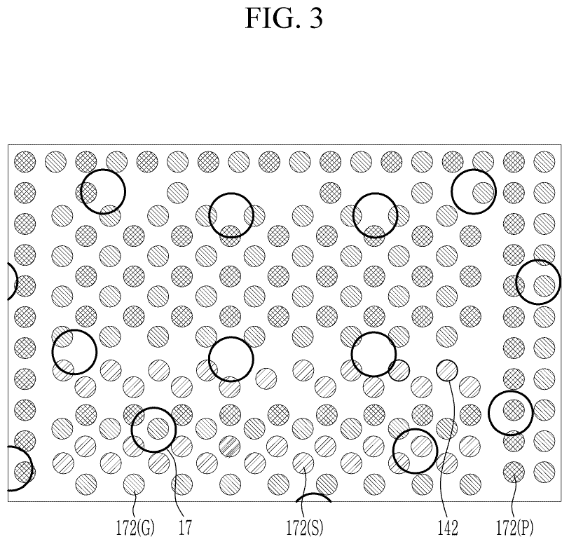

FIG. 2 is a view showing an arrangement of a conductive layer of a conventional substrate 11. FIG. 3 is a top plan view showing a layout of bumps 172 of an embodiment.

The semiconductor package based on a 2.5D semiconductor package applies a high-speed interface IP such as a PCIe or a SerDes. The signals of this high-speed interface IP are ball out through the substrate 11. The substrate 11 includes the lower stacking structure 13, the core layer 14, and the upper stacking structure 15. The lower stacking structure 13 and the upper stacking structure 15 of the substrate 11 are manufactured by stacking conductive layers including a signal layer that transmits the signals, a power layer that transmits the power, and a ground layer that is connected to the ground, as necessary.

Referring to FIG. 2, the conventional substrate 11 includes the core layer 14 made of an organic material. When forming the core through via 17 within the core layer 14 made of the organic material, the core through via 17 of the core layer 14 in the substrate 11 is manufactured to have a diameter D0 of about 250 μm. Because the bump that connects the semiconductor die and the redistribution structure has the diameter of about 30 μm to about 120 μm, the diameter D0 of the core through via 17 of the core layer 14 has the larger size than the diameter of the bump.

Referring to FIG. 3, the footprints of the signal connection member 172(S), the power connection member 172(P), and the ground connection member 172(G) are compared with the footprints of the core through vias 17 in the core layer 14 made of the organic material. The diameter D0 of the core through via 17 of the core layer 14 has the larger size than the diameter of the connection member 172, and the layout of the core through vias 17 cannot be regularly overlapped with the layout of the connection members 172. Since the layout of the core through vias 17 and the layout of the connection members 172 cannot overlap, the signals from the semiconductor die cannot be transmitted directly from the connection members at the bottom of the semiconductor die to the bottom of core layer 14, which is made of the organic material, and all signals have a path that moves in the horizontal direction from the upper stacking structure 15 on the core layer 14.

For this reason, the substrate 11 made of the organic material must have a signal layer disposed within the upper stacking structure 15, and for signals of high-speed interface IP, the Rx signal and the Tx signal must be routed in different layers, respectively, accordingly the upper stacking structure 15 of the substrate 11 must have at least two signal layers.

In addition, the substrate of the semiconductor package to which the high-speed interface IP is applied must be designed to have a strip line structure in which ground layers are disposed above and below the signal layer to reduce a crosstalk. Here, if a power layer is added to supply the power required by high-speed interface IP, in the upper stacking structure 15, six conductive layers of a ground layer-a signal layer-a ground layer-a signal layer-a ground layer-a power layer or seven conductive layers of a power layer-a ground layer-a signal layer-a ground layer-a signal layer-a ground layer-a power layer layers must be disposed.

Referring to FIG. 2 for the substrate 11 including these conductive layers, the upper stacking structure 15 includes a power layer ML8, a ground layer ML9, a signal layer ML10, a ground layer ML11, a signal layer ML12, a ground layer ML13, and a power layer ML14. The lower stacking structure 13 includes seven conductive layers corresponding to the power layer or the ground layer. The large number of the conductive layers within the substrate 11 increases the vertical size of the semiconductor package and causes a complex signal transmission path to be formed between the semiconductor chips and between the semiconductor chip and the substrate 11.

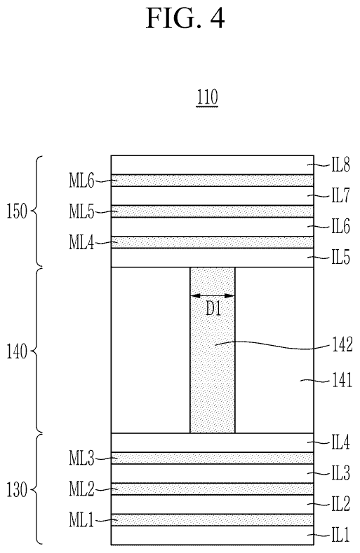

FIG. 4 is a view of an arrangement of conductive layers of a substrate 110 in FIG. 1.

Referring to FIG. 3 and FIG. 4, the core 141 within the core layer 140 of the substrate 110 is made of a material capable of forming a small diameter of the core through via 142. The diameter D1 of the core through via 142 of the core layer 140 has the size similar to the diameter of the connection member 172, and the layout of the core through vias 142 may be regularly overlapped with the layout of the connection members 172. By this structure, the signals from the semiconductor die 170 may be transmitted directly from the connection members 172 below the semiconductor die 170 to the lower stacking structure 130 below the core layer 140. Therefore, one of two signal layers for routing the Rx signal and the Tx signal that must be routed in the different layers may be disposed in the lower stacking structure 130 below the core layer 140, and the other of two signal layers may be disposed in the upper stacking structure 150 above the core layer 140.

Additionally, if the ground layers are disposed above and below each signal layer to reduce the crosstalk, the lower stacking structure 130 includes three conductive layers of the ground layer ML1, the first signal layer ML2, and the ground layer ML3, and the upper stacking structure 150 includes three conductive layers of the ground layer ML4, the second signal layer ML5, and the ground layer ML6.

According to the present disclosure, the core 141 of the substrate 110 may be made of a material that can form a small diameter of the core through via 142, so that the number of the conductive layers may be reduced compared to the conventional substrate 11. As a result, the vertical size of the semiconductor package may be reduced and the signal transmission path between the substrate 110 and the semiconductor die 170 may be efficiently configured.

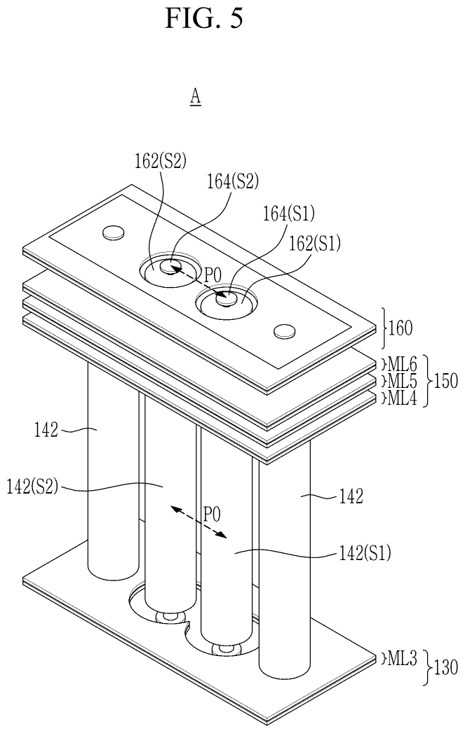

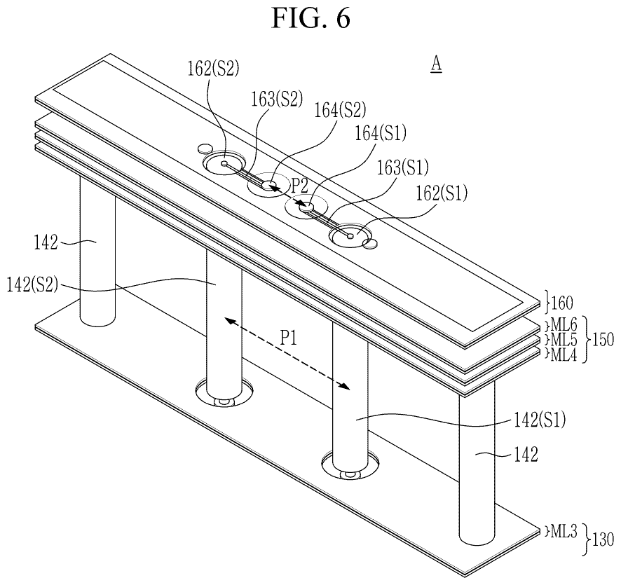

FIG. 5 is a perspective view showing a comparative example of a region A of a semiconductor package in FIG. 1. FIG. 5 and FIG. 6 show the third conductive layer ML3 of the lower stacking structure 130, the core through vias 142 of the core layer 140, the fourth conductive layer ML4 to the sixth conductive layer ML6 of the upper stacking structure 150, and the redistribution structure 160, and omit the first conductive layer ML1, the second conductive layer ML2, the first dielectric material layer IL1 to the fourth dielectric material layer IL4 of the lower stacking structure 130, the core 141 of the core layer 140, the fifth dielectric material layer IL5 to the eighth dielectric material layer IL8 of the upper stacking structure 150, and the dielectric material 161 of the redistribution structure 160.

Referring to FIG. 5, the core 141 of the substrate 110 is made of a material capable of forming a small diameter of the core through via 142. One of two signal layers for routing the Rx signal and the Tx signal that must be routed in the different layers may be disposed in the lower stacking structure 130 below the core layer 140, and the other of two signal layers may be disposed in the upper stacking structure 150 above the core layer 140. With this structure, the signals from the semiconductor die 170 may be routed directly along the signal vertical path from the connection members 172 below the semiconductor die 170, through the redistribution structure 160 and the core layer 140, to the signal layer of the lower stacking structure 130. The spacing of the neighboring connection members 172 in the horizontal direction among the connection members 172 below the semiconductor die 170 is about 50 μm to about 180 μm, so that the distance P0 between the neighboring signal vertical paths among the signal vertical paths extending from the connection members 172 to the signal layer of the lower stacking structure 130 is also formed similarly to the spacing of the neighboring connection members 172 in the horizontal direction. For example, the distance P0 between the neighboring signal vertical paths among the signal vertical paths extending from the connection members 172 to the signal layer of the lower stacking structure 130 is also about 50 μm to about 180 μm.

The signal vertical paths through which the pair of differential signals of the N signal and the P signal are routed must be designed to satisfy the target impedance. The target impedance of the differential signal is affected by the spacing between the signal vertical paths. When the distance between the neighboring signal vertical paths among the signal vertical paths extending from the connection members 172 to the signal layer of the lower stacking structure 130 is formed small, or when the distance between one of the signal vertical paths extending from the connection members 172 to the signal layer of the lower stacking structure 130 and the neighboring ground vertical path is formed small, the target impedance of the differential signal decreases, and a signal integrity (SI) deteriorates.

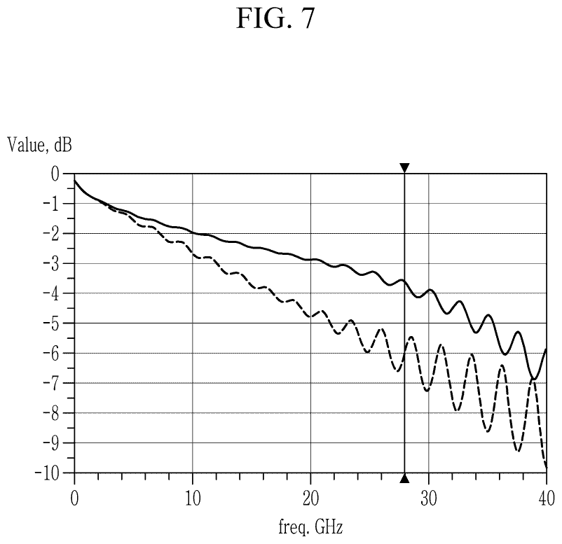

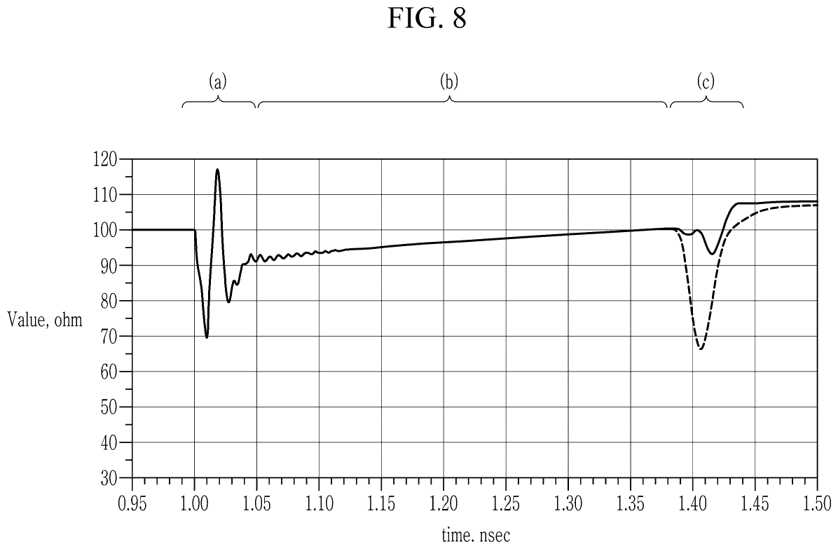

FIG. 6 is an enlarged perspective view of a region A of a semiconductor package 100 in FIG. 1. FIG. 7 is a graph showing a comparison of an insertion loss for a region A of a conventional semiconductor package and an insertion loss for a region A of a semiconductor package according to an embodiment. FIG. 8 is a graph showing a comparison of a return loss for a region A of a conventional semiconductor package and a return loss for a region A of a semiconductor package according to an embodiment.

Referring to FIG. 1 and FIG. 6, the semiconductor package 100 includes first signal paths, second signal paths, ground paths, power paths. In an embodiment, the first signal paths may route one of the Rx signal and the Tx signal, and the second signal paths may route the other of the Rx signal and the Tx signal.

Each of the first signal paths may route one of the signal S1 (the N signal; the first signal) and the signal S2 (the P signal; the second signal) of the differential signal. The first signal path includes a first horizontal path, a first vertical path, a second horizontal path, and a second vertical path. The first horizontal path includes one (133S1 or 133S2) of the signal lines 133S in the first signal layer ML2. The first vertical path includes one (134S1 or 134S2) of the first signal vias 134S between the signal lines 133S and the core through via 142, one (142S1 or 142S2) of the core through vias 142, one (155S1 or 155S2) of the second signal vias 155S penetrating the upper stacking structure 150, and one (162S1 or 162S2) of the first redistribution vias 162. The second horizontal path includes one of the redistribution lines 163 (163S1 or 163S2). The second vertical path includes one (164S1 or 164S2) of the second redistribution vias 164, one (165S1 or 165S2) of the bonding pads 165, and one (172S1 or 172S2) of the connection members 172. Each of the first signal paths passes through the first signal layer ML2 within the lower stacking structure 130. The footprint of the first vertical path and the footprint of the second vertical path are included within the footprint of the semiconductor die 170.

Since the target impedance of the differential signal decreases as the spacing between signal vertical paths becomes closer, according to the present disclosure, by designing the second horizontal path within the redistribution structure 160, it is possible to secure the distance between the signal vertical paths that may satisfy the target impedance of the differential signal. The neighboring first vertical paths routing the signal S1 and the signal S2 of the differential signal extend with the first spacing P1 in the horizontal direction. In an embodiment, the first spacing P1 may be about 200 μm to about 500 μm. The neighboring second vertical paths routing the signal S1 and the signal S2 of the differential signal extend with the second spacing P2 in the horizontal direction. In an embodiment, the second spacing P2 may be about 50 μm to about 180 μm. The first spacing P1 is larger than the second spacing P2. In an embodiment, the second horizontal path of the signal S1 may extend in a direction away from the second vertical path of the signal S2. In an embodiment, the second horizontal path of the signal S2 may extend in a direction away from the second vertical path of the signal S1. In this way, the second vertical paths with the close spacing and the first vertical paths with the extended spacing may be connected with the second horizontal path.

Referring to FIG. 7, as a result of testing the insertion loss before and after forming the second horizontal path, the insertion loss of the differential signal according to the comparative example in FIG. 5 (represented by a dotted line) was measured to be about −6 dB at 28 GHz of a basic frequency of SerDes, and the insertion loss of the differential signal according to the present disclosure (represented by a solid line) was measured to be about −3.6 dB at 28 GHz. According to the present disclosure, the insertion loss of the differential signal may be improved by about 44%, and the loss of the differential signal may be effectively reduced.

Referring to FIG. 8, a TDR (Time-Domain Reflectometry), which calculates the signal reflected from the ball to derive the impedance, was tested under conditions before and after forming the second horizontal path. (a) is a ball region, (b) is a trace region, and (c) is a bump and core via region. The impedance value (a dotted line) in the region (c) according to the comparative example in FIG. 5 is 60 ohm, resulting in a result that is much lower than the target impedance of about 90 ohm, and an impedance discontinuity characteristic appeared. In contrast, it may be seen that the impedance value (a solid line) in the region (c) according to present disclosure has a value between about 90 ohm and about 100 ohm, and the impedance values of the regions (a) and (b) are maintained and the impedance discontinuity is improved. Therefore, according to the present disclosure, the signal integrity (SI) of the semiconductor package 100 may be improved.

Again, coming back to FIG. 1, each of the second signal paths may route one of the signal S1 (the N signal; the first signal) and the signal S2 (the P signal; the second signal) of the differential signal. The second signal path includes the first vertical path, the second horizontal path, and the second vertical path. The first vertical path includes one of the signal vias 135S passing through the lower stacking structure 130, one of the core through vias 142S, and one of the signal vias 152S of the upper stacking structure 150. The second horizontal path includes one of the signal lines 153S in the second signal layer ML5. The second vertical path includes one of the signal vias 154S of the upper stacking structure 150, one of the first redistribution vias 162S, one of the redistribution lines 163S, one of the second redistribution vias 164S, one of the bonding pads 165S, and one of the connection members 172S. Each of the second signal paths passes through the second signal layer ML5 within the upper stacking structure 150.

Each of the ground paths includes one of the ground layer (ML1 and ML3) and the via, the core through vias 142G within the lower stacking structure 130, one of the ground layer (ML4 and ML5) and the via within the upper stacking structure 150, the first redistribution vias 162G, one of the redistribution lines 163G, one of the second redistribution vias 164G, one of the bonding pads 165G, and one of the connection members 172G.

Each of the power paths includes one of the vias 135P of the lower stacking structure 130, one of the core through vias 142P, one of the vias 155P of the upper stacking structure 150, one of the first redistribution vias 162P, one of the redistribution lines 163P, one of the second redistribution vias 164P, one of the bonding pads 165P, and one of the connection members 172P.

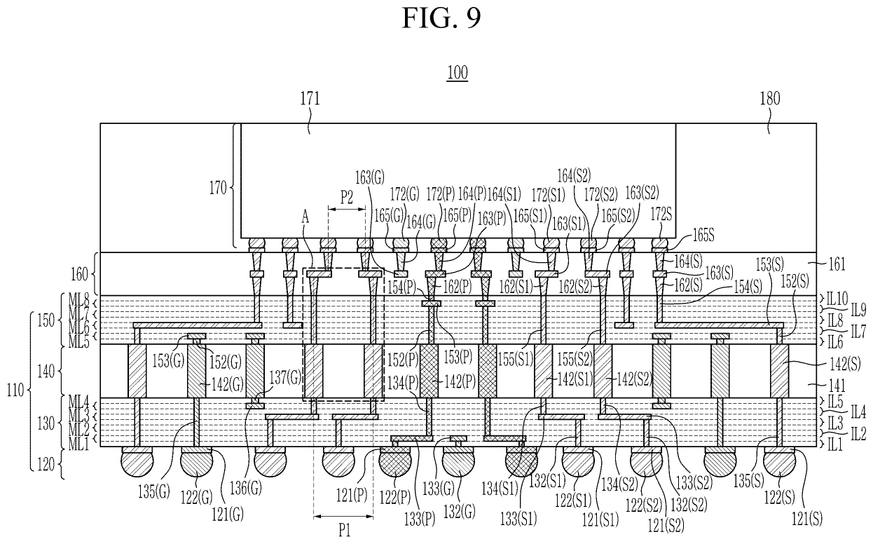

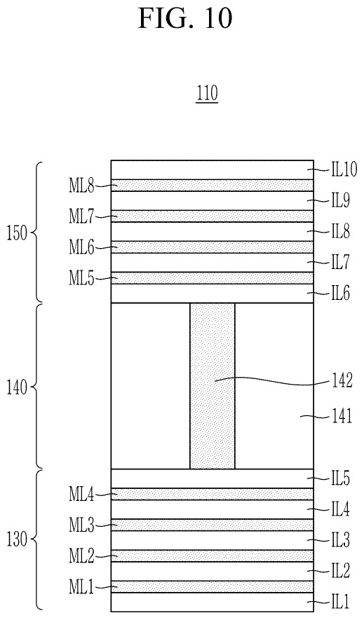

FIG. 9 is a cross-sectional view showing a semiconductor package 100 of another embodiment. FIG. 10 is a view of an arrangement of conductive layers of a substrate 110 in FIG. 9.

Referring to FIG. 9 and FIG. 10, compared with the embodiment FIG. 1, in order to supply a power required for high-speed interface IP, the upper stacking structure 150 of the substrate 110 further includes a power layer. The lower stacking structure 130 includes N stacked conductive layers. In an embodiment, N may be 4. The lower stacking structure 130 includes four conductive layers of the power layer ML1, the ground layer ML2, the first signal layer ML3, and the ground layer ML4, or four conductive layers of the ground layer ML1, the ground layer ML2, the first signal layer ML3, and the ground layer ML4. The upper stacking structure 150 includes M stacked conductive layers. In an embodiment, M may be 4. The upper stacking structure 150 includes four conductive layers of the ground layer ML5, the second signal layer ML6, the ground layer ML7, and the power layer ML8. As a result, the number of the conductive layers in the substrate may be reduced compared to the conventional art, so the size of the semiconductor package may be reduced, and the signal transmission path between the semiconductor chip and the substrate may be implemented more efficiently.

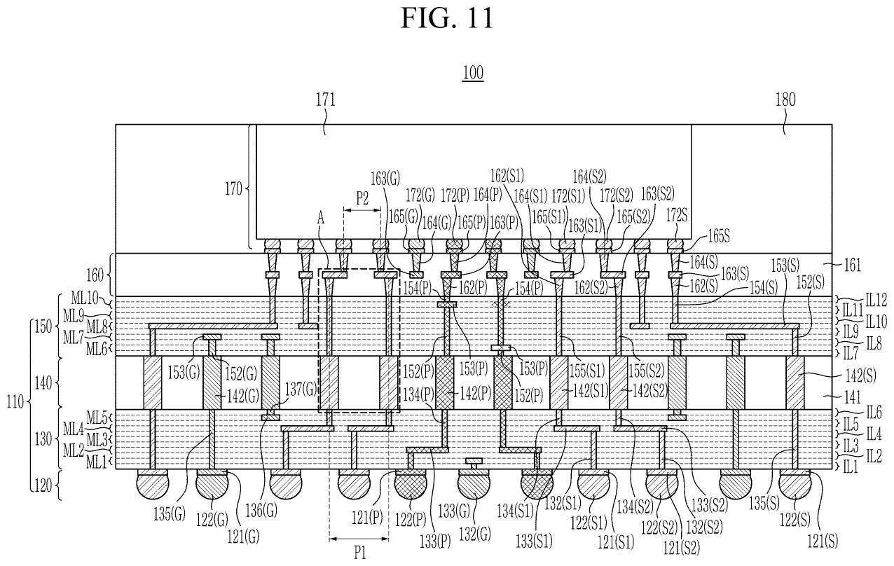

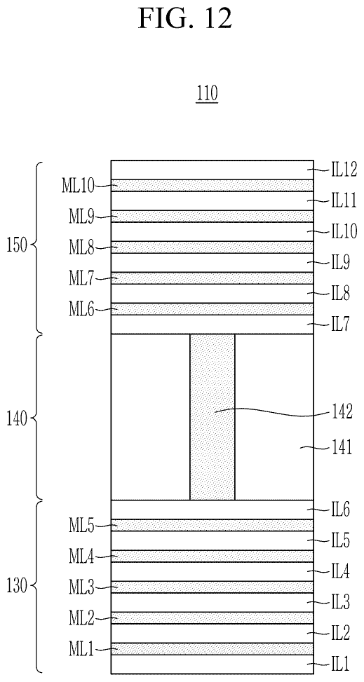

FIG. 11 is a cross-sectional view showing a semiconductor package 100 according to another embodiment. FIG. 12 is a view of an arrangement of conductive layers of a substrate 110 in FIG. 11.

Referring to FIG. 11 and FIG. 12, compared with the embodiment of FIG. 1, in order to supply the power required for high-speed interface IP, the upper stacking structure 150 of the substrate 110 further includes two power layers. The lower stacking structure 130 includes N stacked conductive layers. In an embodiment, N may be 5. The lower stacking structure 130 includes five conductive layers of the power layer or ground layer ML1, the power layer or ground layer ML2, the ground layer ML3, the first signal layer ML4, and the ground layer ML5. The upper stacking structure 150 includes M stacked conductive layers. In an embodiment, M may be 5. The upper stacking structure 150 includes five conductive layers of the power layer ML6, the ground layer ML7, the second signal layer ML8, the ground layer ML9, and the power layer ML10. As a result, the number of the conductive layers in the substrate may be reduced compared to the conventional art, so the size of the semiconductor package may be reduced, and the signal transmission path between the semiconductor chip and the substrate may be implemented more efficiently.

The above-described semiconductor package according to embodiments may be included in various electronic products including display devices, televisions, computers (e.g., laptops), phones (e.g., smartphones), severs, infotainment systems, or the like.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a substrate including a first signal layer, a core layer on the first signal layer, and a second signal layer on the core layer;
a redistribution structure disposed on the substrate and including a plurality of redistribution lines; and
a semiconductor die on the redistribution structure,
wherein a signal transmitted to or from the semiconductor die is routed through:
a first horizontal path within the first signal layer;
a first vertical path extending from the first signal layer to a corresponding redistribution line among the plurality of redistribution lines;
a second horizontal path within the corresponding redistribution line; and
a second vertical path extending from the corresponding redistribution line to the semiconductor die.

2. The semiconductor package of claim 1, wherein:
the substrate includes a glass substrate.

3. The semiconductor package of claim 1, wherein:
a footprint of the first vertical path and a footprint of the second vertical path are included within a footprint of the semiconductor die.

4. The semiconductor package of claim 1, wherein:
a bottom surface of the redistribution structure is in contact with a top surface of the substrate.

5. The semiconductor package of claim 1, wherein:
the substrate includes:
a first stacking structure including N stacked conductive layers, wherein one of the N stacked conductive layers is a first signal layer and N is a natural number;
the core layer on the first stacking structure; and
a second stacking structure disposed on the core layer and including M stacked conductive layers, wherein one of the M stacked conductive layers is a second signal layer and M is a natural number.

6. The semiconductor package of claim 5, wherein:
N and M are 3, 4 or 5.

7. The semiconductor package of claim 5, wherein:
the first stacking structure includes:
a first ground layer;
the first signal layer on the first ground layer; and
a second ground layer on the first signal layer, and
the second stacking structure includes:
a third ground layer;
the second signal layer on the third ground layer; and
a fourth ground layer on the second signal layer.

8. The semiconductor package of claim 7, wherein:
the second stacking structure further includes a power layer on the fourth ground layer.

9. The semiconductor package of claim 8, wherein:
the second stacking structure further includes an additional power layer below the third ground layer.

10. A semiconductor package comprising:
a substrate including a first signal layer, a core layer on the first signal layer, and a second signal layer on the core layer;
a redistribution structure disposed on the substrate and including a plurality of redistribution lines; and
a semiconductor die on the redistribution structure,
wherein each of a first signal and a second signal transmitted to or from the semiconductor die is routed through:
a first horizontal path within the first signal layer;
a first vertical path extending from the first signal layer to a corresponding redistribution line among the plurality of redistribution lines;
a second horizontal path within the corresponding redistribution line; and
a second vertical path extending from the corresponding redistribution line to the semiconductor die,
the first vertical path of the first signal and the first vertical path of the second signal extend with a first spacing in a horizontal direction,
the second vertical path of the first signal and the second vertical path of the second signal extend with a second spacing in the horizontal direction, and
the first spacing is greater than the second spacing.

11. The semiconductor package of claim 10, wherein:
the first signal and the second signal are a differential signal.

12. The semiconductor package of claim 10, wherein:
the first spacing is about 200 μm to about 500 μm.

13. The semiconductor package of claim 10, wherein:
the second spacing is about 50 μm to about 180 μm.

14. The semiconductor package of claim 10, wherein:
the second horizontal path of the first signal extends in a direction away from the second vertical path of the second signal, and
the second horizontal path of the second signal extends in a direction away from the second vertical path of the first signal.

15. A semiconductor package comprising:
a substrate, wherein the substrate includes:
a signal layer including a plurality of signal lines;
a plurality of first signal vias on the plurality of signal lines;
a core layer including a plurality of core through vias on the plurality of first signal vias; and
a plurality of second signal vias on the plurality of core through vias,
a redistribution structure on the substrate, wherein the redistribution structure includes:
a plurality of first redistribution signal vias on the plurality of second signal vias;
a plurality of redistribution signal lines on the plurality of first redistribution signal vias; and
a plurality of second redistribution signal vias on the plurality of redistribution signal lines,
a plurality of connection members on the redistribution structure; and
a semiconductor die on the plurality of connection members,
each of a plurality of signals transmitted to or from the semiconductor die is routed through:
one first horizontal path among the plurality of signal lines;
a first vertical path through one of the plurality of first signal vias, one of the plurality of core through vias, one of the plurality of second signal vias, and one of the plurality of first redistribution signal vias;
one second horizontal path among the plurality of second redistribution signal lines; and
a second vertical path through one of the plurality of second redistribution signal vias and one of the plurality of connection members,
the first vertical paths of neighboring signals among the plurality of signals extend with a first spacing in a horizontal direction,
the second vertical paths of neighboring signals among the plurality of signals extend with a second spacing in the horizontal direction, and
the first spacing is greater than the second spacing.

16. The semiconductor package of claim 15, wherein:
the plurality of connection members include a micro bump.

17. The semiconductor package of claim 15, wherein:
each of the plurality of core through vias has a diameter of about 30 μm to about 120 μm in the horizontal direction.

18. The semiconductor package of claim 15, wherein:
each of the plurality of connection members has a diameter of about 30 μm to about 120 μm in the horizontal direction.

19. The semiconductor package of claim 15, wherein:
a spacing between neighboring cores through vias among the plurality of core through vias in the horizontal direction is about 200 μm to about 500 μm.

20. The semiconductor package of claim 15, wherein:
the core layer includes glass, and
the plurality of core through vias are a through glass via (TGV).
